(19) United States
(12) Patent Application Publication
(10) Pub. No.: US 2026/0290673 A1
(43) Pub. Date: Sep. 24, 2026

(54) INTEGRATED INDUCTOR-CAPACITOR STRUCTURE FOR VOLTAGE CONVERTERS

(71) Applicant: Micron Technology, Inc., Boise, ID (US)

(72) Inventors: Carlos Jesus Franco Tinoco, Boise, ID (US); Dale Arnold, Meridian, ID (US); Ekram H. Bhuiyan, Sunnyvale, CA (US)

(21) Appl. No.: 19/549,631

(22) Filed: Feb. 25, 2026

Related U.S. Application Data
(60) Provisional application No. 63/773,742, filed on Mar. 18, 2025.

(51) Int. Cl. H01F 27/28; H01F 27/40; H03H 7/01

(52) U.S. Cl. CPC H01F 27/28; H01F 27/40; H03H 7/0115

(57) ABSTRACT

Apparatuses and systems are provided for an inductor-capacitor (LC) structure that is part of or coupled to a voltage converter. The LC structure can include a capacitor and an inductor comprising a plurality of coils. At least a portion of the plurality of coils wraps around the capacitor so as for the inductor to form an integrated structure with the capacitor.

### PRIORITY INFORMATION

This application claims the benefit of U.S. Provisional Application Number 63/773,742, filed on Mar 18, 2025, the contents of which are incorporated herein by reference.

### TECHNICAL FIELD

The present disclosure relates generally to electronic systems, and more particularly to an integrated inductor-capacitor structure for voltage converters

### BACKGROUND

Voltage regulators play essential roles in supplying power to subsystems with distinct voltage and current needs. Linear regulators offer simplicity and low noise, while switching regulators, such as buck, boost, and buck-boost converters, achieve high efficiency for variable loads. For example, power management integrated circuits (PMICs) often integrate multiple voltage regulators and other functions, reducing board space and complexity while ensuring precise coordination across power rails in devices like smartphones, laptops, and embedded systems.

### BRIEF DESCRIPTION OF THE DRAWINGS

FIG. 1 illustrates a voltage regulation component including a voltage converter coupled to an integrated inductor-capacitor (LC) structure in accordance with a number of embodiments of the present disclosure.

FIG. 2 illustrates a portion of an environment having an example integrated LC structure in accordance with a number of embodiments of the present disclosure.

FIG. 3 is a top view of an example integrated LC structure in accordance with a number of embodiments of the present disclosure.

FIG. 4 illustrates a portion of an environment having an example integrated LC structure and a substrate in accordance with a number of embodiments of the present disclosure.

FIG. 5 illustrates an example computing environment that includes a memory system having an integrated LC structure in accordance with various embodiments of the present disclosure.

### DETAILED DESCRIPTION

Embodiments of the present disclosure describe systems and apparatuses associated with integrated inductor-capacitor (LC) structure for voltage converters. The voltage converters can be implemented within electrical systems, which can be memory systems, among others. Example memory systems can include multichip package (MCP) storage systems such as a UFS-based MCP (uMCP), a managed NAND (mNAND), etc. Such MCPs can include multiple memory types (e.g., DRAM, NAND, etc.) and a controller (e.g., ASIC) in a single package. Reducing or maintaining the size and cost of the MCP storage systems while increasing thermal and power efficiency is desirable, particularly for mobile applications such as cellular phones.

Converters such as switching DC/DC buck converters employ inductors to perform the step-down voltage conversion, and can offer a competitive advantage over Low Dropout (LDO) solutions due to superior power efficiency. However, integrating DC/DC converters into electrical systems, such as MCP storage systems may present significant challenges, particularly with the use of inductors for step-down voltage conversion. Current device-mounted inductors, ranging from 220 nH to 470 nH, may be too large to fit within the aggressive size constraints of modern package designs. This results in increased costs and limited real estate on the MCP storage systems for additional passive components.

Moreover, package inductors face technical limitations, including coreless substrates with fewer than four layers, a height restriction of less than 130 micrometer (μm), and reliance on laser vias. These constraints demand compensation for inductance and parasitic resistance to ensure effective power conversion. For low-power applications requiring less than 200 mA, achieving inductances above 25 nH within a small footprint is particularly difficult, creating a need for innovative solutions to address these limitations. Overall, attempts to make these designs smaller (to be suitable for the MCP storage systems with the height restriction) often introduced new challenges. As the size was reduced, maintaining stable and predictable behavior became more difficult, which impacted the overall quality of the output.

Embodiments of the present disclosure address the above and other challenges by providing a voltage converter in which the capacitor and inductor are compactly integrated together, reducing the overall footprint without compromising performance. Further, this avoids the need to sacrifice the other properties of MCP storage systems (e.g., increasing the height of the MCP storage systems) to implement the existing LC filter.

Advanced manufacturing techniques and precise alignment of embodiments of the present disclosure minimize parasitic interactions, achieving a balance between size and electrical stability that was previously unattainable. These manufacturing techniques are designed to meet specific mechanical and design conditions to ensure reliable performance. For example, the total die stack thickness is required to exceed the capacitor thickness (of the LC filter), allowing proper wire overlap during assembly. Additionally, the width of the capacitor must be carefully dimensioned to provide sufficient wire length for secure and stable connections.

To facilitate proper wire bonding, the distance between the capacitor and the leads are configured to provide adequate space for the landing of wedge or stitch bonds. When epoxy material is used, the design can account for potential outgassing effects to prevent interference with the bonding process. Furthermore, the lead pitch can be precisely calculated to accommodate the wire loop height, ensuring the wires do not interfere with the capillary walls during bonding operations.

In addition, a staggered lead design is can be used to mitigate potential interference between the capacitor and the wires, reducing the likelihood of wire shorts. To further ensure mechanical stability and electrical reliability, the lead width for ball bonding can be designed with a minimum dimension of 80 μm. These considerations address challenges associated with the mechanical and electrical integration of components, enabling the development of compact, high-performance devices.

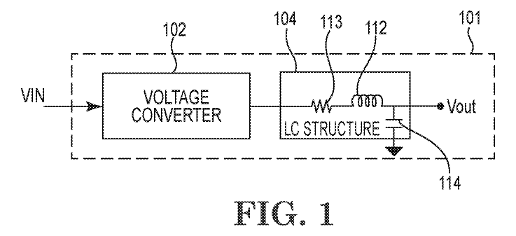

FIG. 1 illustrates a voltage regulation component 101 including a voltage converter 102 coupled to an integrated inductor-capacitor (LC) structure 104 in accordance with a number of embodiments of the present disclosure. The voltage regulation component 101 includes a voltage converter 102 and an LC structure 104 coupled to an output node of the voltage converter 102. The voltage regulation component 101 can receive an input voltage (“VIN” shown in FIG. 1) and generates an output voltage (“VOUT” shown in FIG. 1) that may be different from the input voltage. For example, it can step the voltage up, step it down, or regulate the output voltage to maintain a desired level. The voltage regulation component 101 can include or be a low-dropout (LDO) regulator, a buck-boost converter, a buck regulator, a boost regulator, or combinations thereof, although embodiments are not so limited. In addition to these regulators, the voltage regulation component 101 can also function as a step-up (boost) converter, a step-down (buck) converter, an inverter, a rectifier, or an isolated converter, among others. More particularly, the voltage regulation component 101 can be a DC-DC (e.g., buck) converter, although embodiments are not so limited. In some embodiments, the input voltage can be 2.5V, while the output voltage can be 0.8V, although embodiments are not so limited.

The LC structure 104 (alternatively referred to as an “integrated LC structure”) is coupled to an output node of the voltage converter 102. The LC structure 104 includes an inductor 112 and a capacitor 114. In various embodiments, the LC structure 104 can be an LC filter. The LC filter 104 can smooth or filter the output voltage of the voltage converter 102, reducing ripple and improving voltage quality.

The LC structure 104 further comprises a resistor 113 coupled between the inductor 112 and the converter 102. The resistor 113 can reduce ripple voltage, minimize resonance at the LC cutoff frequency, and enhance system damping, resulting in a cleaner output from the converter 102.

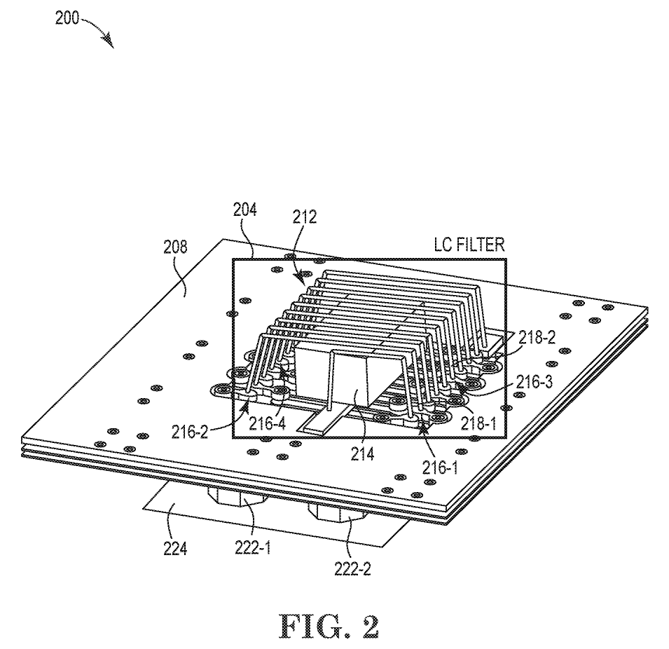

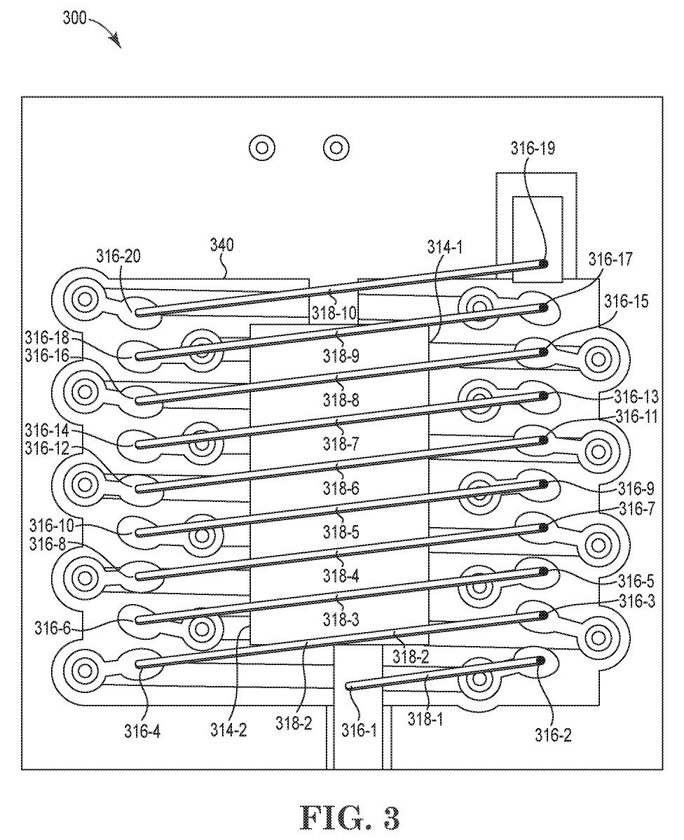

In a number of embodiments, the inductor 112 and the capacitor 114 can be integrated to one another in a manner that physically combines them into a single structure. More particularly, as further illustrated in FIGS. 2 and 3, coils (alternatively referred to as “loops”) of the inductor 112 can be wrapped around or positioned in proximity to the capacitor 114 to form a compact and unified structure.

FIG. 2 illustrates a portion of an environment 200 having an example integrated LC structure 204 (“LC filter” shown in FIG. 2) in accordance with a number of embodiments of the present disclosure. The integrated LC structure 204 shown in FIG. 2 is analogous to the integrated LC structure 104 shown in FIG. 1. Similarly, the inductor 212 and the capacitor 214 of the LC filter 204 are analogous to the inductor 112 and the capacitor 114, respectively, shown in FIG. 1.

The LC structure 204 can be formed on a substrate 208, which can be a multilayer substrate, in some embodiments. While embodiments are not limited to a particular quantity of layers the substrate 208 can include, the substrate can be a 3-layer or 4-layer substrate. As described herein, the multilayer substrate 220 refers to multiple stacked layers of materials. The layers can be composed of various substrate materials and the choice of materials for each layer may depend on specific requirements of the device being fabricated.

The substrate 208 can then be coupled to a base 224, such as a Printed Circuit Board (PCB). For example, the substrate 208 can be coupled to the base 224 via ball grid arrays (BGAs), such as BGAs 222-1, 222-2.

As shown in FIG. 2, the inductor 212 includes a plurality of coils respectively formed between two nodes. As an example, a coil 218-1 (e.g., of the plurality of coils) of the inductor 212 is coupled between the node 216-1 (positioned adjacent to one side of the capacitor 214) and the node 216-2 (positioned adjacent to the opposite side of the capacitor 214). As another example, a coil 218-2 (e.g., of the plurality of coils) of the inductor 212 is coupled between the node 216-3 (positioned adjacent to one side of the capacitor 214) and the node 216-4 (positioned adjacent to the opposite side of the capacitor 214).

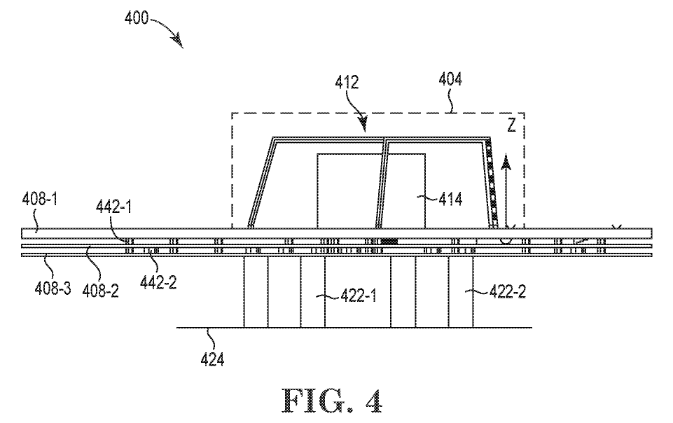

As used herein, the term “node” refers to either a connection point by which two entities are coupled to one another. For example, although embodiments are not so limited, nodes can be soldered joints, connector pins, pads, sockets, headers, solder balls, such as ball grid array (BGA) balls, solder bumps, various metal contacts, etc. by which the entities can be connected/coupled to one another. As an example, nodes 216 can refer to respective connection points via which the coils 218 are connected/coupled to any one of layers (e.g., layers 408-1, 408-2, 408-3 shown in FIG. 4) of the substrate 208 or an intermediate point.

As shown in FIG. 2, the coils 218 are wire bonded to the nodes 216 on the substrate. In some embodiments, the nodes 216 can be conductive nodes to provide electrical connectivity (to further provide electrical connectivity to the other components on the substrate 208) and designed to anchor the coils 218 to the substrate.

FIG. 3 is a top view of a portion of an electronic system 300 including an example integrated LC structure 304 in accordance with a number of embodiments of the present disclosure. The integrated LC structure 304 (alternatively referred to as “LC filter”) shown in FIG. 3 is analogous to the LC structure 104, 204 respectively shown in FIGS. 1 and 2. For example, the inductor 312 and the capacitor 314 of the LC structure 304 can be analogous to the inductor 112, 212 and the capacitor 114, 214 respectively of the LC structure 104, 204.

As illustrated further in FIG. 3, an opening 340 (alternatively referred to as a “specific section”) can be formed at least on a top surface layer (e.g., the layer 408-1 shown in FIG. 4) of the substrate 208. The LC filter can be formed on this specific section of the substrate 208 with an area not exceeding one square millimeter (e.g., dimensions of 1.2 mm by 0.8 mm).

The view (e.g., top view) shown in FIG. 3 provides a two-dimensional representation of the environment 300. The view captures the intersection of features of the environment 300 as seen from a specific perspective. This specific perspective can be a depiction of a “plane” (e.g., a two-dimensional surface that extends infinitely in all directions, such as in “X” and “Y” axis) that may or may not be at the same height as (e.g., various surfaces or portions of) inductor 312, capacitor 314, coils 318, and/or the substrate 308 illustrated in FIG. 3, which may exist in a third dimension (e.g., corresponding to “Z”-axis) not defined by the plane’s two dimensions. For example, while the inductor 312, capacitor 314, coils 318, and/or the substrate 308 may not be precisely positioned or located on the plane shown FIG. 3, the plane can illustrate the points, lines, and/or patterns on the plane that are obtained as a result of (e.g., resulting from) the projection of the inductor 312, capacitor 314, coils 318, and/or the substrate 308 onto the plane. The plane shown in FIG. 3 can be substantially parallel to the top surface (e.g., opposite to the surface that is in contact with at least a portion of the substrate 308) of the capacitor 314.

FIG. 3 illustrates a plurality of coils 318-1, …, 318-10 (collectively referred to as coils 318) that collectively form an inductor (e.g., the inductor 212). As further illustrated in FIG. 3, each coil is coupled between respective two nodes 316-1, …, 316-20 (collectively referred to as 316). For example, the coil 318-1 is coupled between the nodes 316-1 and 316-2; the coil 318-2 is coupled between the nodes 316-3 and 316-4; the coil 318-3 is coupled between the nodes 316-5 and 316-6; the coil 318-4 is coupled between the nodes 316-7 and 316-8; the coil 318-5 is coupled between the nodes 316-9 and 316-10; the coil 318-6 is coupled between the nodes 316-11 and 316-12; the coil 318-7 is coupled between the nodes 316-13 and 316-14; the coil 318-8 is coupled between the nodes 316-15 and 316-16; the coil 318-9 is coupled between the nodes 316-17 and 316-18; and the coil 318-10 is coupled between the nodes 316-19 and 316-20.

The coils 318 can be parallel with each other and can be horizontally aligned. The term “substantially” intends that the characteristic need not be absolute but is close enough to achieve the advantages of the characteristic. For example, “substantially parallel” is not limited to characteristics that are absolutely parallel and can include characteristics that are intended to be parallel but due to manufacturing limitations may not be precisely parallel.

The coils 318 are formed on the substrate in a manner that they wrap around the capacitor 314 such that each coil 318 extends across the capacitor 314 from one side (e.g., 314-1) to the other (e.g., 314-2), forming an integrated configuration. Alternatively speaking, each coil 318 extends further across the capacitor 314 to the opposite side of the substrate 308.

For example, each set of nodes, between which a respective coil is coupled, can be positioned on opposite sides (314-1, 314-2 shown in FIG. 3) of the capacitor 314. More particularly, the node 316-3 is positioned adjacent to (e.g., closer to) side 314-1 of the inductor 314, while the node 316-4 is positioned adjacent to (e.g., closer to) side 314-2 of the inductor 314. This arrangement causes the coil 318-1, as projected on the plane shown in FIG. 3 and formed between the nodes 316-3 and 316-4, to intersect with at least side 314-1 on the same plane. More particularly, the node 316-5 is positioned adjacent to (e.g., closer to) side 314-1 of the inductor 314, while the node 316-6 is positioned adjacent to (e.g., closer to) side 314-2 of the inductor 314. This arrangement causes the coil 318-1, as projected on the plane shown in FIG. 3 and formed between the nodes 316-5 and 316-6, to intersect with both sides 314-1, 314-2 on the same plane.

FIG. 4 illustrates a portion of an environment 400 having an example integrated LC structure 404 (“LC filter” shown in FIG. 4) and a substrate 408 including a plurality of layers 408-1, 408-2, and 408-3 in accordance with a number of embodiments of the present disclosure. The integrated LC structure 404 (alternatively referred to as “LC filter”) shown in FIG. 4 is analogous to the LC structure 104, 204, 304 respectively shown in FIGS. 1-3. For example, the inductor 412 and the capacitor 314 of the LC structure 304 can be analogous to the inductor 112, 212, 312 and the capacitor 114, 214, 314 respectively of the LC structure 104, 204, 304. Further, the substrate 408 can be analogous to the substrate 208, 308 illustrated in FIGS. 2-3, respectively. As shown in FIG. 4, the substrate 408 can be further coupled to the base 424 via BGAs, such as BGAs 422-1, 422-2.

As shown in FIG. 4, the layers 408-1, 408-2, 408-3 of the multilayer substrate 220 can be interconnected using interconnecting vias (e.g., micro vias). For example, as illustrated in FIG. 4, the layers 408-1, 408-2, 408-3 can be coupled to one another via the interconnecting via 442-1, while the layers 408-2 and 408-3 can be coupled to one another via the interconnecting via 442-2.

In a number of embodiments, one or more layers 408-1, 408-2, 408-3 may include a shielding layer for the inductor 412. The shielding layers may provide proper grounding to minimize electromagnetic leakage, reducing electromagnetic interference (EMI) and parasitic capacitances, which can negatively impact the performance and efficiency of the voltage converter. In some embodiments, the shielding layers 222 and/or 225 may comprise insulators.

Although embodiments are not limited to these dimensions, the capacitor 414 can have a length (e.g., the length of either side 314-1 or 314-2) ranging from 0.35 mm to 0.45 mm, a width (e.g., the length of the sides of the capacitor 414 that are substantially perpendicular to sides 314-1 and 314-2 on the “X” and “Y” dimensions) ranging from 0.15 mm to 0.25 mm, and a thickness (e.g., height, such as the “Z” shown in FIG. 4) ranging from 0.15 mm to 0.25 mm. As used herein, the height “Z” refers to the vertical distance measured perpendicular to the plane of the substrate (the green layers) along the z-axis, from the top surface of the substrate to the highest point of the LC structure, such as the apex of the coils 412. In some embodiments, the inductor (e.g., coils 218, 318 shown in FIGS. and 3, respectively) extend over the substrate to a height of no more than 0.3 millimeters (mm).

The integrated structure 404 provides advantages over previous approaches, particularly through its stable inductive response of approximately 30 nH across a wide frequency range from direct current (DC) (e.g., 0Hz) to 1 GHz. More particularly, this stability ensures reliable performance across diverse operating conditions, making it ideal for modern high-frequency power systems and DC-DC converters operating within the 100 MHz to 250 MHz switching frequency range. Unlike the previous approaches, which often exhibited frequency-dependent instability and size constraints, the compact and efficient form factor of this solution reduces parasitic effects while maintaining performance comparable to larger systems. Additionally, the resonance frequency near 1 GHz is positioned well beyond the typical operating range, ensuring it does not interfere with the converter's normal operation. This is a beneficial design feature, as it minimizes the impact of resonance on the desired performance within the 100 MHz to 250 MHz range.

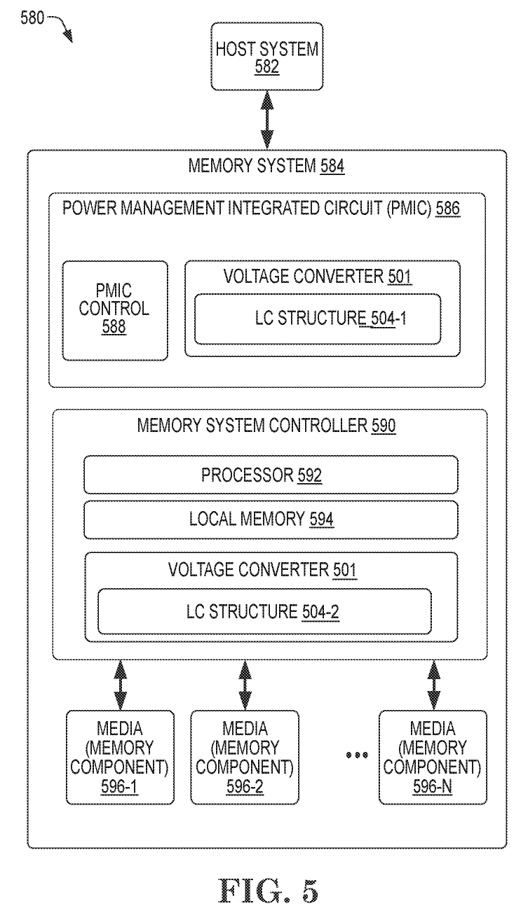

FIG. 5 illustrates an example computing environment 580 that includes a memory system 584 in accordance with some embodiments of the present disclosure. In some embodiments, a host system 582 is coupled to the memory system 584 to read data from or write data to the memory system 584. The memory system 584 may further include a power management component such as a power management integrated circuit (PMIC) 588, a memory system controller 590, and memory components 596-1 to 596-N. In various embodiments, the PMIC 588 and/or controller 590 can be separate chips within an MCP. The memory system 584 can be a storage device, a memory module, or a hybrid of a storage device and a memory module. Examples of storage devices include a solid-state drive (SSD), a managed NAND (mNAND), a Universal Flash Storage (UFS) drive, a secure digital (SD) card, and a hard disk drive (HDD). Examples of memory modules include a dual in-line memory module (DIMM) and various types of non-volatile dual in-line memory modules (NVDIMMs). In general, the host 582 can utilize the memory system 584 which includes one or more memory components. The host 582 can provide data to be stored at the memory system 584 and can request data to be retrieved from the memory system 584.

The host system 582 can be a computing device such as a desktop computer, laptop computer, network server, mobile device, or such computing device that includes a memory and a processing device. The host system 582 can be coupled to the memory system 584 via a physical host interface. As used herein, “coupled to” generally refers to a connection between components, which can be an indirect communicative connection or direct communicative connection (e.g., without intervening components), whether wired or wireless, including connections such as electrical, optical, magnetic, etc. Examples of a physical host interface include but are not limited to, a serial advanced technology attachment (SATA) interface, a peripheral component interconnect express (PCIe) interface, universal serial bus (USB) interface, Fibre Channel, Serial Attached SCSI (SAS), etc. The physical host interface can be used to transmit data between the host system 582 and the memory system 584. The host system 582 can further utilize an NVM Express (NVMe) interface to access the memory components 596-1 to 596-N when the memory system 584 is coupled with the host system 582 by the PCIe interface. The physical host interface can provide an interface for passing control, address, data, and other signals between the memory system 584 and the host system 582.

The memory components 596-1 to 596-N can include various combinations of the different types of non-volatile memory components and/or volatile memory components. An example of non-volatile memory component includes a NAND flash memory. Each of the memory components 596-1 to 596-N can include one or more arrays of memory cells such as single-level cells (SLCs) or multi-level cells (MLCs) (e.g., triple-level cells (TLCs) or quad-level cells (QLCs)). In some embodiments, a particular memory component can include both an SLC portion and an MLC portion of memory cells. Each of the memory cells can store one or more bits of data (e.g., data blocks) used by the host system 582. Although non-volatile memory components such as NAND type flash memory are described, the memory components 596-1 to 596-N can be based on various memory technologies and/or array architectures. In some embodiments, the memory components 596-1 to 596-N can be but are not limited to, random access memory (RAM), read-only memory (ROM), dynamic random access memory (DRAM), synchronous dynamic random access memory (SDRAM), phase change memory (PCM), magneto random access memory (MRAM), negative-or (NOR) flash memory, electrically erasable programmable read-only memory (EEPROM), and which can be arranged as a planar array, a cross-point array, three-dimensional cross-point array, etc.

At least one of the memory components 596 can include multiple memory dies that may be, for example in a stacked configuration. For example, multiple memory dies in the stacked configuration may comprise a stack of memory dies (e.g., dies stacked onto one another) with through silicon vias (TSVs) through which signaling may be routed. An example of the memory components 596 in the stacked configuration can be high-bandwidth memory (HBM) cubes having various heights (e.g., 16H stack, 16 DRAM memory dies).

The memory system controller 590 can communicate with the memory components 596-1 to 596-N to perform operations such as reading data, writing data, or erasing data at the memory components 596-1 to 596-N and other such operations. The memory system controller 590 can include hardware such as one or more integrated circuits and/or discrete components, a buffer memory, or a combination thereof. The memory system controller 590 can be a microcontroller, special purpose logic circuitry (e.g., a field programmable gate array (FPGA), an application specific integrated circuit (ASIC), etc.), or other suitable processing circuitry. The memory system controller 590 can include a processing device (e.g., processor 592) configured to execute instructions stored in a local memory 594.

The local memory 594 of the memory system controller 590 includes an embedded memory configured to store instructions for performing various processes, operations, logic flows, and routines that control the operation of the memory system 584, including handling communications between the memory system 584 and the host system 582. In some embodiments, the local memory 594 can include memory registers storing memory pointers, fetched data, etc. The local memory 594 can also include read-only memory (ROM) for storing microcode.

In general, the memory system controller 590 can receive commands or operations from the host system 582 and can convert the commands or operations into instructions or appropriate commands to achieve the desired access to the memory components 596-1 to 596-N. The memory system controller 590 can be responsible for other operations such as wear leveling operations, garbage collection operations, error detection and error-correcting code (ECC) operations, encryption operations, caching operations, and address translations between a logical block address and a physical block address that are associated with the memory components 596-1 to 596-N. The memory system controller 590 can further include host interface circuitry to communicate with the host system 582 via a physical host interface (not shown). The host interface circuitry can convert the commands received from the host system into command instructions to access the memory components 596-1 to 596-N as well as convert responses associated with the memory components 596-1 to 596-N into information for the host system 582.

The memory system 584 can also include additional circuitry or components that are not illustrated. For instance, the memory components 596-1 to 596-N can include control circuitry (e.g., a local controller), address circuitry (e.g., row and column decode circuitry), and/or input/output (I/O) circuitry by which they can communicate with memory system controller 590 and/or host system 582. As an example, in some embodiments, the address circuitry (not shown) can receive an address from the memory system controller 590 and decode the address to access the memory components 596-1 to 596-N.

The PMIC 588 can be a chip configured to manage power within the system 584. For example, the PMIC 588 can include one or more voltage converter components (e.g., 501-1) to generate output voltages (e.g., rail voltages) such as I/O rails, reference rails, etc. that are provided to power various system components, such as controller 590, memory components 596, and/or interfaces associated therewith. As shown in FIG. 5, the PMIC 588, memory system controller 590, or both, may include corresponding voltage converter components (e.g., 501-1 and 501-2, which are referred to collectively as voltage converter components 501).

The voltage converter components 501 can be respectively analogous to the voltage converter component 101. For example, the voltage converter components 501 can include one or more voltage converters (respectively analogous to the voltage converter 102 shown in FIG. 1) be inductor-based voltage converters (e.g., buck converters) that include corresponding LC structures (e.g., the LC structures 504-1 and 504-2 that are respectively analogous to the LC structure 104, 204, 304, and 404), which can be drawn in the substrate of the MCP storage systems, for example.

MCP storage systems such as system 584 often have a reduced thickness (e.g., limited quantity of substrate and/or thin substrate layers), which provides limited available real estate for inductor-based voltages converter components such as 501-1 and 501-2. Embodiments of the present disclosure addresses these challenges through a particular design, in which the capacitor and inductor are compactly integrated together (as shown in FIGS. 2-4), reducing the overall footprint without compromising performance.

The PMIC 588 can include control circuitry (not shown), which is configured to control the various components of the PMIC 588, such as voltage converter component 501-1. Although not shown in FIG. 5, the voltage converter components 501 include additional circuitry such as input/output capacitors, diodes, transistor switches, fuses, feedback networks, etc.

Although not shown, the inductors and/or capacitors of the LC structures 504-1 and 504-2 are coupled to other components of the voltage converter to which they correspond (e.g., diodes, transistors, etc.) to generate the desired output voltages. In various embodiments, the LC structures 504 may be formed in the multilayer substrate of MCP storage system, such as the multiplayer substrate of the PMIC 588, memory system controller 590, memory components 596 or both.

The figures herein follow a numbering convention in which the first digit or digits correspond to the drawing figure number and the remaining digits identify an element or component in the drawing. Similar (e.g., the same) elements or components between different figures may be identified by the use of similar digits. For example, an LC structure 204 can refer to element “04” in FIG. 2, and a similar element in can be referred to using an LC structure 404 in FIG. 4. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of turns can refer to one or more turns. A “plurality” of something intends two or more. As used herein, multiple acts being performed concurrently refer to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause-and-effect relationship). An element coupled between two elements can be between the two elements and coupled to each of the two elements. Unless stated otherwise, where a single element is discussed, it is understood that all similar elements are referred to. It should be recognized the term planar accounts for variations from “exactly” planar due to routine manufacturing, measuring, and/or assembly variations and that one of ordinary skill in the art would know what is meant by the term “planar.”

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. An apparatus, comprising:
a voltage converter; and
an inductor-capacitor (LC) structure coupled to the voltage converter, the LC structure comprising:
a capacitor; and
an inductor comprising a plurality of coils, wherein at least a portion of the plurality of coils wraps around the capacitor so as for the inductor to form an integrated structure with the capacitor.

2. The apparatus of claim 1, wherein the LC structure corresponds to an LC filter configured to filter an output voltage of the voltage converter.

3. The apparatus of claim 1, wherein the inductor and the capacitor are formed on a substrate.

4. The apparatus of claim 3, wherein:
each coil of the at least the portion of the plurality of coils is coupled between a respective one of a plurality of first nodes and a respective one of a plurality of second nodes.

5. The apparatus of claim 4, wherein:
the respective one of the plurality of first nodes is positioned on the substrate and adjacent to a first side of the capacitor; and
the respective one of the plurality of first nodes is positioned on the substrate and adjacent to a second side of the capacitor such that each coil of the at least the portion of the plurality of coils extends across the capacitor from the first side to the second side or from the second side to the first side.

6. The apparatus of claim 4, wherein:
each coil of the at least the portion of the plurality of coils extends across the capacitor to the opposite side of the substrate.

7. The apparatus of claim 3, wherein the plurality of coils extend over the substrate to a height of no more than 0.3 millimeters (mm).

8. The apparatus of claim 3, wherein the substrate comprises a plurality of layers.

9. The apparatus of claim 1, wherein the voltage converter is a DC/DC buck converter, boost converter, or buck-boost converter.

10. The apparatus of claim 1, wherein the inductor has a length between 0.35 millimeters (mm) and 0.45 mm, a width between 0.15 mm and 0.25 mm, and a thickness between 0.15 mm and 0.25 mm.

11. An apparatus, comprising:
a voltage converter; and
an inductor-capacitor (LC) structure coupled to the voltage converter and formed on a substrate, the LC structure comprising:
an inductor comprising a plurality of coils; and
a capacitor positioned underneath of at least a portion of the plurality of coils of the inductor such that the at least the portion of the plurality of coils wraps around the capacitor.

12. The apparatus of claim 11, wherein:
each of the plurality of coils is formed between two respective nodes of a plurality of nodes on the substrate; and
at least a portion of the plurality of nodes is positioned on opposite sides of the capacitor.

13. The apparatus of claim 11, wherein the substrate comprises a plurality of layers having four or fewer layers.

14. A system, comprising:
a number of memory components of a storage system; and
a voltage regulation component:
a voltage converter; and
an inductor-capacitor (LC) filter coupled to the voltage converter, the LC filter comprising:
a capacitor; and
an inductor comprising a plurality of coils, wherein at least a portion of the plurality of coils wraps around the capacitor so as for the inductor to form an integrated structure with the capacitor.

15. The system of claim 14, wherein the voltage regulation component and at least a portion of the number of memory components are formed on a substrate.

16. The system of claim 15, wherein:
at least one of memory components further comprises a stack of memory dies stacked on the substrate; and
wherein a first height of the stack of memory dies is greater than a second height of a plurality of coils of the inductor, wherein the first and the second heights respectively correspond to a vertical distance measured perpendicular to a plane of the substrate.

17. The system of claim 16, wherein the first height is no more than 130 micrometers (μm).

18. The system of claim 15, wherein the LC filter is formed on a particular section of the substrate with an area not exceeding one square millimeter.

19. The system of claim 14, wherein the storage system is a multichip package (MCP) storage system.

20. The system of claim 14, wherein the system is one of a managed NAND storage system or a universal flash storage (UFS) based storage system.
